(19) United States
(12) Patent Application Publication
(10) Pub. No.: US 2011/0175603 A1
(43) Pub. Date: Jul. 21, 2011

(54) Method and Apparatus for Measuring Magnetic Fields

(76) Inventors: Vladimir Burtman, Salt Lake City, UT (US); Michael S. Zhdanov, Salt Lake City, UT (US)

(21) Appl. No.: 12/997,239

(22) PCT Filed: Jun. 12, 2009
(86) PCT No.: PCT/US09/47208

§ 371 Date: Mar. 14, 2011

Related U.S. Application Data
(60) Provisional application No. 61/061,294, filed on Jun. 13, 2008.

(51) Int. Cl. G01R 33/02

(52) U.S. Cl. 324/244

(57) ABSTRACT

A new ultra-sensitive magnetometer is disclosed and described. The ultra-sensitive magnetometer relies on non-tunneling magneto-transport (MT) and control of MT in organic solid state devices. These organic devices can have different active components as magnetic and non-magnetic polymers and self-assembled monolayers (SAMs). Magnetic field sensors can include a pair of electrodes spaced apart from one another. An organic layer can be oriented between the pair of electrodes to form an organic solid state device, wherein at least one of the organic layer and electrodes is magnetic and when the organic layer is not magnetic the organic layer comprises a self assembled monolayer and the magnetic field sensor operates under non-tunneling magnetic spin transport.

### BACKGROUND OF THE INVENTION

Magnetic field sensing technology has been driven by the need for improved sensitivity, smaller size, and compatibility with electronic interfaces. Magnetic sensing applications include Homeland Security applications, military applications and military surveillance, medical applications include MRI, magnetocardiography, and defect detection. Magnetic sensors can be useful for biosensors for laboratory-on-a-chip systems and for medical imaging. Electronics applications include devices such as magnetoresistive random-access memory (MRAM) and computer logic devices, non-destructive testing, replacements for electromechanical magnetic switches, and microelectromechanical system (MEMS) reed switches in the industry. Compact magnetic sensors can be used in navigation systems, flexible magneto-electronic and magneto-optic components. For example, magnetic sensors can be used in feedback loops of positioning devices. In addition, for geological and military surveillance, highly sensitive magnetic sensors can be used in unmanned aerial vehicles to map magnetic and geological features.

Magnetic sensors that are currently available are limited in use by their cost and complexity. Many types of sensitive magnetic sensors require significant cryogenic cooling in order to function properly. The cost and complexity of state of the art magnetic sensors limits the number of application in which they can be used.

### SUMMARY OF THE INVENTION

Systems and methods for measuring a magnetic field and forming sensors therefore are disclosed. A system for measuring a magnetic field comprises at least two electrodes. A sensing channel comprising an organic material is located between the at least two electrodes. A magnetic field detection device is coupled to the at least two electrodes and configured to determine a strength of the magnetic field based on a change in current flow through the sensing channel.

### BRIEF DESCRIPTION OF THE DRAWINGS

FIG. 1A provides an exemplary illustration of a system for measuring a magnetic field according to one embodiment of principles described herein.

FIG. 1B illustrates a schematic structure the device of FIG. 1a in accordance to an embodiment of principles described herein.

FIGS. 2A-D provides an illustration of a process for producing a SAM device for measuring a magnetic field in accordance with an embodiment of principles described herein.

FIGS. 3A-C illustrate graphs of magnetoresistance measurements.

FIGS. 4A-C illustrate graphs of chemical doping of V(TCNE)₂ which results in a V-Co(TCNE)₂ system that remains at room temperature with a tunable hysteresis width in accordance with an embodiment of principles described herein.

FIGS. 5A and 5B provide alternative structures for the illustrations of FIGS. 1a and 1b, in accordance with an embodiment of principles described herein.

It will be understood that these figures are provided merely for convenience in describing the invention and are drawn for purposes of clarity rather than scale. As such, actual dimensions may, and likely will, deviate from those illustrated in terms of relative dimensions and the like. Furthermore, these figures are non-limiting examples of various specific embodiments of the present invention.

### DETAILED DESCRIPTION

Reference will now be made to the exemplary embodiments illustrated in the drawings, and specific language will be used herein to describe the same. It will nevertheless be understood that no limitation of the scope of the invention is thereby intended. Alterations and further modifications of the inventive features illustrated herein, and additional applications of the principles of the inventions as illustrated herein, which would occur to one skilled in the relevant art and having possession of this disclosure, are to be considered within the scope of the invention.

It must be noted that, as used in this specification and the appended claims, the singular forms “a,” “an,” and “the” include plural referents unless the context clearly dictates otherwise. Thus, for example, reference to “a polymer” includes one or more of such materials, reference to “a phosphor” includes reference to one or more of such elements, and reference to a “forming” step includes reference to one or more of such steps.

Definitions

In describing and claiming the present invention, the following terminology will be used in accordance with the definitions set forth below.

As used herein, “nanosize” particles refers to any molecule or compound measuring less than 1 μm. Most often nanosize particles of the present invention are smaller than 100 nm. Such dimensions include at least one of or all of: length, width, height, and diameter.

As used herein, “polymer” refers to one or more polymers existing or coexisting with other polymer or material. This definition includes mixtures or composites involving at least one polymer.

As used herein, “magnetic field” refers to magnetic field or flux, static or dynamic.

As used herein, “react” or “reacting” refers to any interaction between the identified materials which results in an association of the identified materials. A reaction of materials can result in formation and/or destruction of chemical bonds, ionic association, or the like.

As used herein, “substantially” or “substantial” refers to the complete or nearly complete extent or degree of an action, characteristic, property, state, structure, item, or result. For example, an object that is “substantially” enclosed would mean that the object is either completely enclosed or nearly completely enclosed. The exact allowable degree of deviation from absolute completeness may in some cases depend on the specific context. However, generally speaking, the nearness of completion will be so as to have the same overall result as if absolute and total completion were obtained. The use of “substantially” is equally applicable when used in a negative connotation to refer to the complete or near complete lack of action, characteristic, property, state, structure, item, or result. For example, a composition that is “substantially free of” particles would either completely lack particles, or so nearly completely lack particles that the effect would be the same as if it completely lacked particles. In other words, a composition that is “substantially free of” an ingredient or element may still contain such an item as long as there is no measurable effect thereof.

As used herein, “about” is used to provide flexibility to a numerical range endpoint by providing that a given value may be “a little above” or “a little below” the endpoint. The degree of flexibility of this term can be dictated by the particular variable and would be within the knowledge of those skilled in the art to determine based on experience and the associated description herein.

As used herein, a plurality of items, structural elements, compositional elements, and/or materials may be presented in a common list for convenience. However, these lists should be construed as though each member of the list is individually identified as a separate and unique member. Thus, no individual member of such list should be construed as a de facto equivalent of any other member of the same list solely based on their presentation in a common group without indications to the contrary.

Concentrations, amounts, and other numerical data may be expressed or presented herein in a range format. It is to be understood that such a range format is used merely for convenience and brevity and thus should be interpreted flexibly to include not only the numerical values explicitly recited as the limits of the range, but also to include all the individual numerical values or sub-ranges encompassed within that range as if each numerical value and sub-range is explicitly recited.

As an illustration, a numerical range of “about 10 to about 50” should be interpreted to include not only the explicitly recited values of about 10 to about 50, but also include individual values and sub-ranges within the indicated range. Thus, included in this numerical range are individual values such as 20, 30, and 40 and sub-ranges such as from 10-30, from 20-40, and from 30-50, etc. This same principle applies to ranges reciting only one numerical value. Furthermore, such an interpretation should apply regardless of the breadth of the range or the characteristics being described.

Invention

An ultra-sensitive magnetometer operable to measure low magnetic fields is disclosed and described. This magnetometer is also synonymously referred to as a magnetic sensor. The ultra-sensitive magnetometer relies on non-tunneling magneto-transport (MT) and control of MT in organic solid state devices. The term “MT in organic devices” is used to distinguish the present invention devices and materials from “traditional” tunneling magnetoresistance (tunneling MR) or tunneling giant magnetoresistance (tunneling GMR) devices, which are mostly based on the use of inorganic materials. The organic devices in the MT magnetometer can include different active components including magnetic and non-magnetic polymers and self-assembled monolayers (SAMs).

In accordance with one embodiment, a method for measuring magnetic fields is disclosed. The method involves a direct measurement, based on a deviation or alternation of uncompensated spin state transfer and of spin-polarized currents that occur in hybrid organic-inorganic devices in the presence of a magnetic field. The aspects of control of spin/charge injection and transport in (i) organic media, (ii) diluted organic magnetic semiconductors and (iii) molecular magnetism are disclosed. Unlike devices relying on tunneling GMR, the use of magneto-transport based devices enables the ability to control spin injection and spin transport in organic solids.

The method can include the following steps:

a) electromagnetic field dependent injection or induction of any uncompensated spin states in an organic material;

b) electromagnetic field dependent transfer of the uncompensated spin states from one electrode to another; and

c) a measurement of the current due to the transfer of uncompensated spin states, wherein the magnetic field is proportional to the measured current.

Devices using magneto-transport can be associated with the field of molecular spintronics and magnetism. Molecular spintronics relies on control of spin and charge transport in non-magnetic molecular assemblies and also in room temperature ferromagnetic polymers. Spin current in organic magneto-transport (OMT) devices and charge current in magnetic polymers can be very sensitive to external magnetic fields, including ultra-low magnetic fields. Molecular magnetism designates a relatively recent and emerging field of research that focuses on the use of molecular approaches to design, create and study new classes of magnetic materials in which the properties can be tuned at the molecular level. In the last two decades this field has rapidly evolved from the design of new molecule based magnets possessing higher critical temperatures, toward the development of more complex magnetic materials with one or more functional properties of interest. Functional properties can include bistable magnetic materials with switching properties, or multifunctional materials coupling magnetism with a second property. Additional research has been done in the investigation of nanosized magnetic molecules and other nanostructures exhibiting quantum effects, and materials processing aimed at applications.

The present invention can be used as a substitute for magnetic sensors formed using nuclear magnetic resonance (NMR) detection and radio frequency (RF) coils sensors for geophysics surveys. Despite the fact that high sensitivity to low magnetic field can be achieved using NMR, a high cost (of the instrument itself and its exploitation) and device portability is an inherent problem of NMR instrument, when it is used as a magnetic sensor. The present invention comprises controlling spin injection and spinning transport in organic media, and charging transport in magnetic polymer. This approach can provide a less expensive device with better portability and a faster magnetic field measurement sensor than previous technologies such as NMR and superconducting quantum interference device (SQUID) sensors.

Tunneling devices based on giant magnetoresistance (GMR) in inorganic materials are widely using in microelectronics as reading devices in hard discs and RAM. Tunneling GMRs comprise ferromagnetic alloys sandwiched around an ultrathin nonmagnetic conducting middle layer. Due to the tunneling nature of GMR spintronic devices, an optimal layer thicknesses enhance magnetic-layer antiparallel coupling. The optimal layer thickness can be necessary to keep the sensor in the high-resistance state when no field is applied. If the layers are not the proper thickness, however, the coupling mechanism can destroy the tunneling GMR effect by causing ferromagnetic coupling between the magnetic layers. A typical tunneling GMR sensor has a conducting layer approximately 3 nanometers (nm) thick, although this can vary somewhat depending on the particular materials and configuration.

Geometric and operation restrictions in tunneling GMR spintronics devices, imposed on the ultra-short dimensions of the tunneling channel, impose a geometric restriction on the area that is used as a sensor to measure a magnetic field. A larger sensitive area than is available in tunneling GMR devices can be used to provide low magnetic field sensitivity. The nature of GMR tunneling current dependence on magnetic field is unknown, except some rare cases of unintentional doping of a tunneling channel or interface by magnetic impurities. Thus, it is hard to design and develop such devices. Since a small size is involved, it is hard to calibrate such devices at low magnetic and non-uniform fields. The response of electrodes in a GMR detector typically cannot be split from the change in transparency of the tunneling barrier caused by an external magnetic field. This induces a non-linearity in sensor response. In contrast to sensors using the tunneling GMR current effect, the suggested MT approach imposes manipulation of regular spin current. This concept is much more flexible for measuring low strength magnetic fields than can typically be accomplished with a tunneling GMR device.

Attempts to build industrial MT devices based on inorganic semiconductors in the past has not lead to practical application due to high spin-orbit coupling and hyperfine interaction in inorganic semiconductors, which are not favorable for spintronic type applications. It was also demonstrated that electron-electron interaction in inorganic semiconductors results in loosing of spin memory due to the Spin Coulomb drag effect, which are serious obstacles for spintronic applications. Molecular devices may be well suited for applications requiring spin manipulation because the relative weakness of spin-orbit and hyperfine interactions that occur in many molecules, compared to conventional semiconductor systems, may help to isolate the spin from external degrees of freedom. Indeed the first spintronics study of organic semiconductors reports a spin diffusion length that is about 200 nm.

One difference between tunneling GMR magnetic sensors and MT based sensors is in the physical nature of the sensing current that enables fabricating a new type of magnetic sensors that will not rely on a tunneling current (which is based on delocalization of electron function over the barrier). Rather, the sensing current is based on the MT that occurs in organic devices (i.e. the flow of spin polarized electrons in the organic media). Due to this difference, a greater sensitivity of electron flow in organic media relative to a low strength magnetic field can be expected. In addition, an external electrical field can be used to regulate the sensitivity of MT in organic devices.

At least two types of organic materials and organic devices for magneto-transport in organic devices (non tunneling devices) can be used. A first type of device is a magnetic sensor based on spin transport in non-magnetic organic materials, such as organic self-assembled monolayers, polymers, and/or a combination of organic self-assembled monolayers and polymer. In the first case, a non-organic material will be placed between two magnetic electrodes. The second type of magnetic sensors of the present invention is based on the use of a magnetic polymer placed between either magnetic or non-magnetic electrodes. In both cases, an organic material can be used as a sensing channel. The first type of sensor relies on manipulation of the spin current (non-tunneling) in the non-magnetic polymer. The second type of sensor relies on electron current in the magnetic polymer. In the first case, the spin-flow can be affected by an external magnetic field, while in second case the properties of the conductive magnetic matrix itself should be affected by the external magnetic field.

Room temperature spin polarized injection in organic semiconductor (OSEC) polymer devices such as a LSMO-T₆-LSMO structure can result in a spin diffusion length of about 200 nm. A magnetoresistance (MR) change of up to 10% at a temperature of 300 K and a magnetic field strength of 10 mT can be observed using two terminal devices of nonmagnetic electrodes with an OSEC polymer thin film configuration sandwiched between the electrodes. An MR effect of 40% at 11 K and low fields are observed in OSEC spin-valve devices having magnetic electrodes. In addition, the magnetic field dependent electroluminescence has sensitivity in high and low magnetic fields. These features enable fabrication of organic magnetic sensitive diodes with multi-field sensitivity, with optional proportional light emission output, in addition to a readout of current or voltage.

One embodiment of the current invention substitutes a polymer layer in an organic magneto-transport device with a self assembled monolayer (SAM matrix). The SAM structure can have superior structural order relative to the use of randomly oriented polymers. This substitution can enable better spin delocalization and can improve magnetic sensitivity of organic magnetic sensors by an order of magnitude and thus result in sub-micro-Tesla (μT) sensitivity of the magnetic field detector.

In one embodiment, the present invention can use magneto-transport in organic materials, such as magnetic polymers and self-assembled monolayers. This invention comprises a new molecular engineering approach, which includes (1) materials; and (2) different device configurations and operation schemes and device fabrication and operation mechanisms to fabricate ultra-sensitive magnetic field sensors.

The sensitivity of low-field magnetic sensors may be improved when using organic magnetic devices because of the weak spin-orbit and hyperfine interactions existing in organic molecules compared to inorganic materials. The operation of these devices based on measurement of electrical current through the organic layer when a constant applied bias is applied to the outer electrodes. The value of this current, called “spin-current” is dependent on the strength of the applied magnetic field. The amount of spin-current in the organic layer that is caused by an external magnetic field can be calibrated to enable the spin-current to be proportional to the strength of the magnetic field, as measured in Teslas.

In accordance with the present invention, a low-field magnetic sensor based on organics can utilize different active organic media: (i), semiconductive polymers, (ii) magnetic polymers, known also as molecular magnets and (iii) self-assembled monolayers (SAM). This approach utilizes an enormous spin coherent length in organic semiconductors. Similar structures can be used as a suitable device configuration with sensors having sub-μT sensitivity in a planar electrode configuration. Organic ferromagnets (OFM) may also be used as a detecting channel for low-field magnetic sensors. Such OFM may be used as a conductive channel to tune the magnetometer sensitivity. The approach utilizing molecular magnets relies on electron spin interaction in the sensing element. In one embodiment, the sensing element can be formed using bis-tetracyanoethylene vanadium [V(TCNE)₂]. The use of V(TCNE)₂ is also thought to be novel in the field of magnetic sensors and magnetic-transport.

A SAM magnetic sensor can utilize a change from a naturally disordered polymer to an ordered SAM which can increase spin delocalization and consequently improve the sensor sensitivity.

The devices of the present invention can be assembled utilizing different electrode configurations. For example, all aforementioned devices can be assembled in (1) a planar electrode configuration; (2) a planar electrode configuration with the application of a 3^{rd} electrode (a field effect transistor FET configuration); or (3) a vertical electrode configuration, wherein the active organic layer is bridged between the bottom and upper electrodes.

Although the electrodes can be formed of a variety of materials, the aforementioned devices can be build using magnetic electrodes or non-magnetic one or two electrodes. Electron transport can be spin-dependent even without magnetic electrodes. Magnetic electrodes can be either ferromagnetic (Ni, Fe, Co, Ni—Cr, permoloy alloys etc) or half-metal electrodes (e.g. La Sr₂Mn₂O₃ and derived or substituted ceramic, referred to herein as LSMO). Other compositions of LSMO include La₍₁₋ₓ₎SrₓMnO₃, where x=0.7 and La_{0.7}Sr_{0.3}MnO₃, La_{1.2}Sr_{1.8-x}CaₓMn₂O₇ (x=0, 0.1, 0.2). In the last composition, calcium is also included as part of the electrode composition. LSMO can be doped by rare earth metals or their oxides such as by Nb₂O₅. A rare earth metal can be substituted for Lanthanum, such as Pr_{0.7}Sr_{0.3}MnO₃, where Pr substitutes for La. It may also be referred to as Ln_{0.67}A_{0.33}MnO₃ (Ln=Pr, La; A=Ca, Sr). Magnesium has also been tried as a constituent part of LSMO-family of electrodes. For example, a La_{0.75}Sr_{0.25-x}MgₓMnO₃ composition may be used.

In accordance with another aspect of the present invention, a device using spin transport across a polymer sandwiched between magnetic contacts with arbitrary magnetization directions, which predicts a sub-nano-Tesla (nT) response, can be described as follows. Even a weak magnetic field can significantly modify spin transport in polymers through spin precession. The interplay of spin drift (due to electric field) and spin precession can lead to damped oscillating magnetoresistance as the magnetic field increases.

From the point of device molecular engineering, this invention addresses the need for new approaches to multifunctional organic surface structures by developing concepts, methods, and molecular building blocks with covalent bonding as a unifying theme.

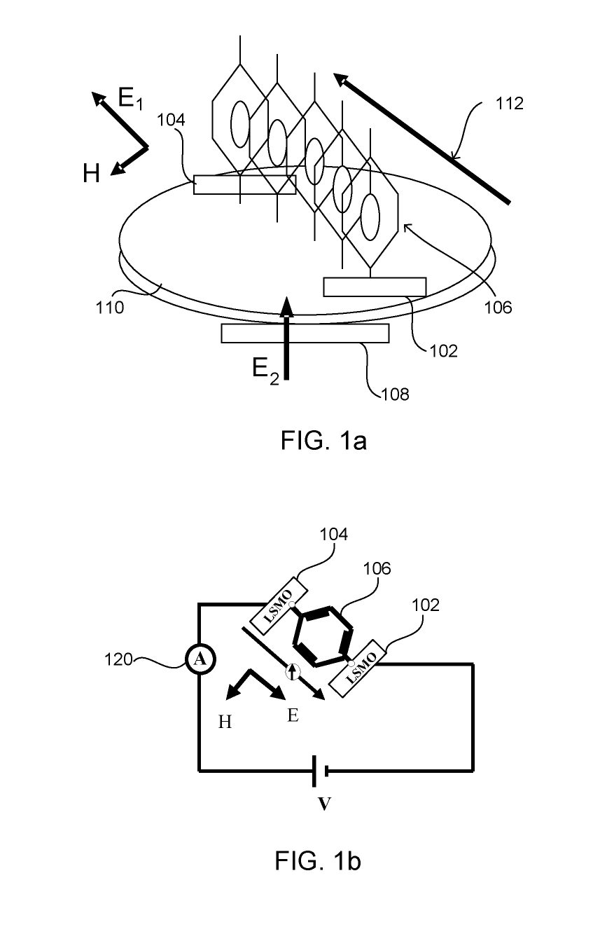

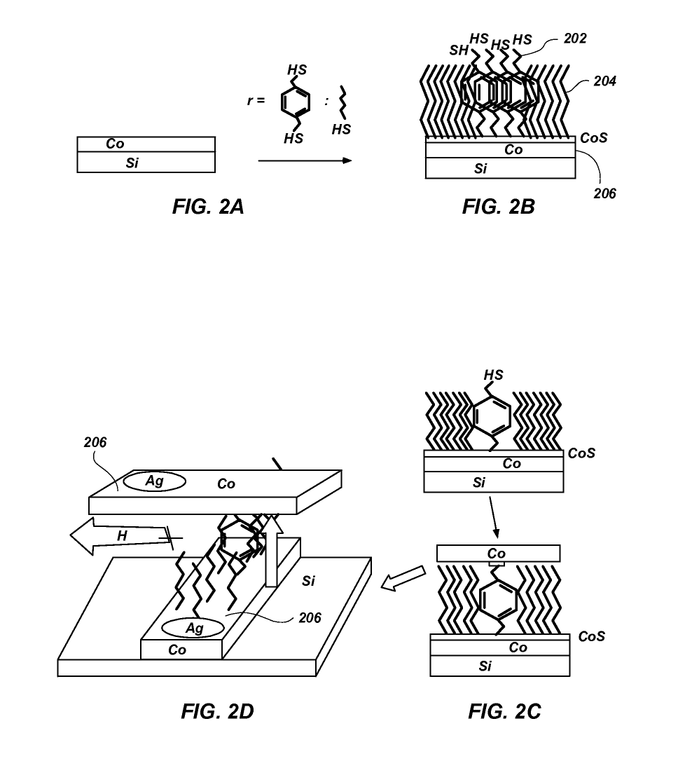

In accordance with one embodiment of principles described herein, a device structure is illustrated in FIG. 1a. In this embodiment, an organic film 106 is shown on top of an insulator 110 contacted by two LSMO electrodes 102, 104. The organic film 106 can be a self-assembled monolayer. A metal strip 108 beneath the insulator 110 may be needed if an electrically controlled magnetic field is desired, such as for a gate field electrode in an FET. The gate field electrode may be formed from a conductive metal such as gold. The insulator material can be formed from a dielectric. The basic device operation can be described as follows. In the absence of a transverse magnetic field, the device resistance is large because either spin species (up or down) must be the minority spin in one of the contacts and neither up-spin nor down-spin carriers can traverse the device easily. When a transverse magnetic field is applied, the spin orientation of carriers will vary over the distance in the polymer (spin precession), which provides a channel connecting the majority spins in the two LSMO contacts, and the resistance is therefore reduced. The electric field formed between the two LSMO contacts also strongly affects spin transport 112 in the devices: (1) it considerably increases spin diffusion length through spin drift; and (2) it determines the transit time of injected carriers in the device and modifies the resistance through the ratio of the transit time and the spin precession time (determined by the magnetic field). The feasibility of fabricating these spin devices is established by recent measurements of spin injections in LSMO/sexithienyl (T6)/LSMO and LSMO/8-hydroxyquinolate aluminum (Alq₃)/Co structures even at room temperature. T6 and Alq₃ are two widely used materials in organic electronics. The observed I-V characteristics in LSMO/T6/LSMO have been explained in theory. In these devices the magnetoresistance is achieved, not by changing the contact magnetizations, but by applying a transverse magnetic field (perpendicular to the contact magnetizations) to induce spin precession.

The device structure of FIG. 1A is shown in a schematic in FIG. 1B. FIG. 1B illustrates a schematic structure of an organic magneto transport (OMT) device to form an ultra-sensitive magnetometer. An organic film 106, such as a self assembling monolayer, is located between two electrodes 102, 104. The electrodes may be formed of a material such as LSMO or cobalt. A voltage V can be applied between the two electrodes. A current can be induced to flow through the organic film 106 in the presence of a transverse magnetic field. The amount of current flowing through the circuit can be measured. In one embodiment, an ammeter 120 can be used to measure the current flowing through the circuit. An ammeter capable of measuring relatively small currents, such as picoamps, can be used to accurately measure extremely small magnetic fields. In addition, a change in capacitance may be measured in the circuit. Alternatively, a fixed current source may be applied and the voltage measured to determine the change in magnetic field when a current is induced. Additional effects that occur at the interface of the electrodes and organic film may also be taken into affect to provide a desired level of accuracy in the measurement of the voltage or current.

SAM Devices

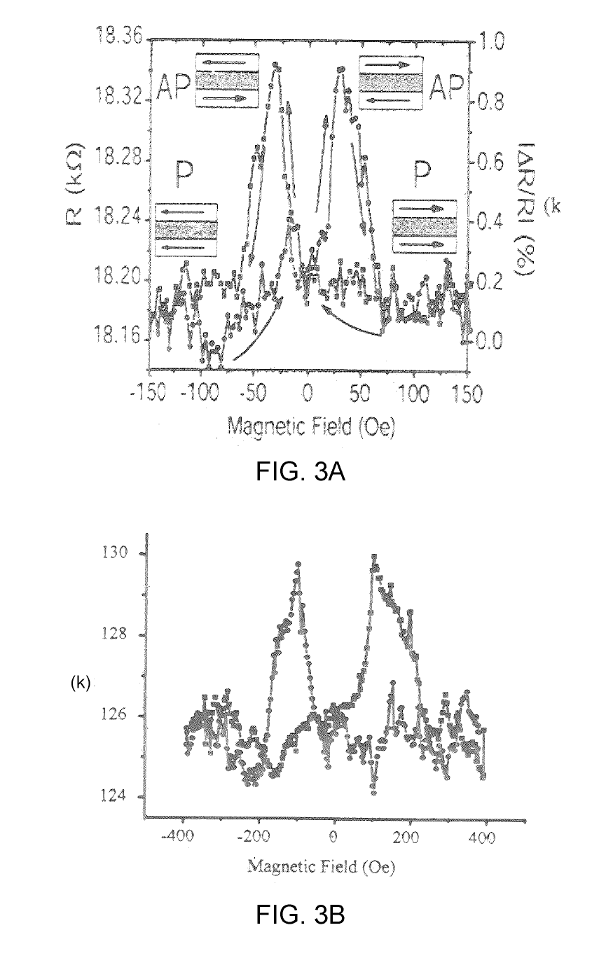

Devices based on organic magneto-transport (OMT) in SAM Solid State Mixtures (SSM) as described schematically in FIGS. 2A-D can also be suitable. Using the SAM SSM approach, a mixture of conductive bis-1,4-(thiomethyl)benzene (Me-BDT) “wires” 202 and dielectric pentanethiol (PT) molecules “spacers” 204 can be self-assembled between two magnetic electrodes made of cobalt 206. When the ratio (r) between the molecular wires 202 and spacers 204 (0<r<1) is small (less than 10⁻⁵), the Me-BDT molecular wires are isolated in the dielectric matrix of PT molecules. In the case of higher r-values (greater than 10⁻⁵) molecular aggregates are formed.

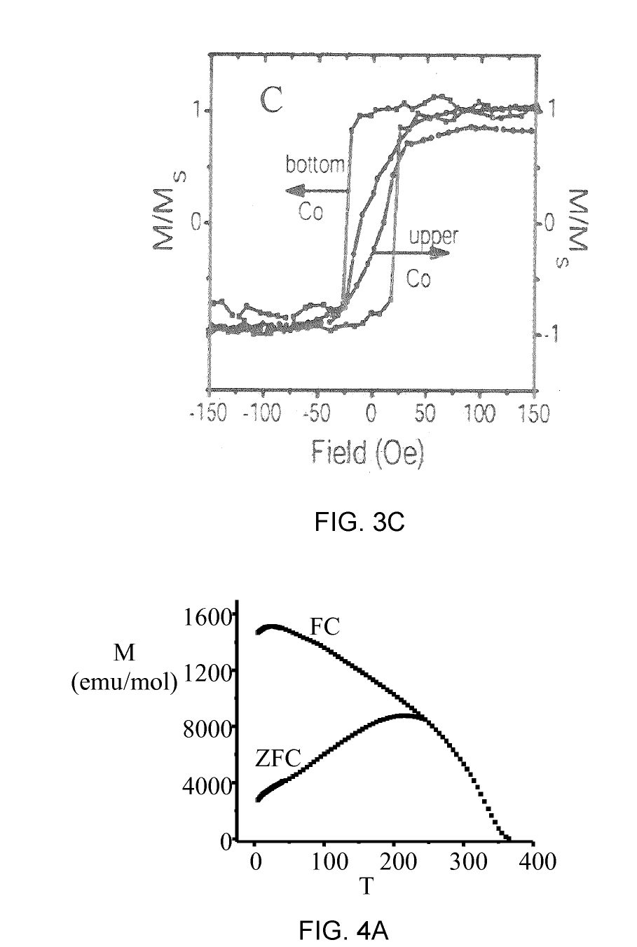

The structural flexibility of a SAM SSM allows fine-tuning of the electronic features. Spin transport results for molecular aggregates and isolated molecular wires are presented in parts A and B of FIG. 3. Spin transport results for molecular aggregates and isolated molecular wires are presented in parts A and B of FIG. 3. Part C demonstrates the different coercive fields (H_{C}) that occur at the bottom and upper Co electrodes, which was studied using the Magnetooptical Kerr Effect (MOKE) measurement. Due to different coercive fields (H_{C}) that occur at the bottom and upper Co electrodes 206 (FIG. 2D bottom panel), a 3.4% MR effect can be observed in molecular aggregates at low temperatures, which decreased to ˜1% at 200K (FIG. 3A). In addition, OMT devices based on isolated wire molecules (FIG. 2B, upper panel) show a change of MR of ˜8% at low temperatures, and ˜4% at 200K (FIG. 3B). Taking into account that only 30% of the charge carriers are spin-polarized in Co, an approximately 90% MR may be achieved in a LSMO-SAM-Co system according to the MR model.

The value of the change in magneto-resistance (ΔMR) is increased at least by an order of magnitude when one of the metal ferromagnetic electrodes is changed to a semi-metal ceramic electrode such as LSMO. Note that MR response is directly proportional to the H_{C} of magnetic electrodes, as shown in FIG. 3C. The electrodes can be fabricated with sub-mT difference in H_{C}. These electrodes can then be used for SAM derived magnetic sensors.

Several non-limiting embodiments can include: 1) Co/SAM/LSMO [bottom (LSMO)-up (Co) vertical design]; 2) Al/SAM/ITO; 3) LSMO-SAM-LSMO [horizontal two terminal design]; and 4) three terminal emitter (SAM)-on-collector (Co—Cu—Co), magnetic-field-effect transistors-device design.

Using SAM Multilayered Structures as Organic Thin Film.

In one embodiment, a method is disclosed of forming a multilayered structure composed of two or more discrete monomolecular layers, or a self-assembled monomolecular layer and a polymer. Although a variety of multilayered structures are possible, non-limiting examples can include (1) saturated, aromatic, or aliphatic organic molecules with two or more reactive groups, which enable self-restricted surface chemistry reactions (amide, amine, aldehyde, Diels-Adler reactions, reactions, chemistry of halogen, thiol, ethoxy and metoxy groups etc); (2) as (1) but metallorganic molecules instead of organic molecules; (3) as (1) and/or (2) or their combinations, with a polymer layer which can have chemically active groups for attached bottom and upper self-assembled monolayers; (4) as (1) and/or (2) and/or (3), but with epitaxially grown inorganic compounds such as GaAs, SiN₃. Here chemistry like chlorine or fluorine, or other epitaxial growth technologies could be used; and (5) as (1), (2), (3) and/or (4), but with silane materials, used to plane the multilayered structure and to avoid the pyramidal growth of multilayer structure. Methods of forming such multilayered structures can include depositing molecules of a selected aliphatic or aromatic compound by liquid phase or vapor phase deposition, onto a substrate having surface-reactive sites capable of reacting with the chemically reactive group in the selected compound. The deposition step is carried under conditions, which allow chemi-sorption of the selected compound in a molecular monolayer, by covalent coupling of one end of the compound to the substrate, and evacuation or sublimation of non-covalently bonded compounds from the surface. For a multilayer growth individual self-assembly steps are carried out one or more times, where the monomolecular layer formed at each deposition cycle forms a new substrate having a surface-exposed monolayer with exposed reactive groups. In one general embodiment, the method includes reacting the surface-exposed monolayer with a bi-functional reagent that reacts with the exposed reactive groups forming the just-deposited layer, to produce a coupling layer having exposed reactive groups with which the reactive groups of the selected compound forming the next monolayer can react.

SAM Chemistry on Different Substrates.

For example, the surface-reactive groups on the substrate can be amine groups, and the bi-functional reagent can be a diamine compound. In this embodiment, the selected compound can be, for example, an anhydride-end compound, having aromatic or aliphatic molecular moiety, capable of forming axial-end imide linkages, a polycyclic diacyl halide, capable of forming axial-end amide linkages, a polycyclic dialdehyde, capable of forming axial-end Schiff base linkages, and a polycyclic diisocyanate, capable of forming axial-end urea linkages. In another general embodiment of the method, the surface-reactive groups on the substrate are maleimide groups, the selected compound is a polycyclic compound with z-axis amine groups, such as a diaminocarbozole, and the bi-functional reagent is a bismaleimide compound.

Organic Magnetic Sensors Based on Magnetic Polymer.

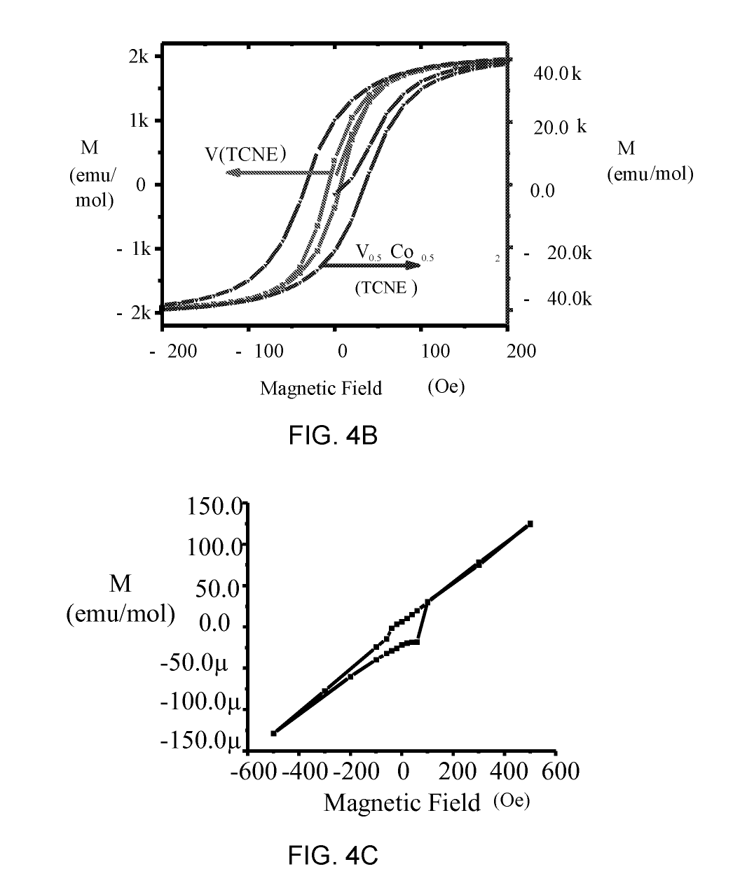

Sensors based on V(TCNE)₂ for the sensing element are suitable for magnetic sensing since this compound is a room temperature Ferro magnet with extremely low H_{c} (6 mT). FIGS. 4A-C illustrate various aspects of the chemical modification of V(TCNE)₂. FIGS. 4A-C illustrate graphs of chemical doping of V(TCNE)₂ results in a V-Co(TCNE)₂ system that remains room temperature (RT) and has a tunable hysteresis width. FIG. 4A shows the field cooled magnetization (FCM) and zero field cooled magnetization (ZFCM) of [V_{0.5}−Co_{0.5}] (TCNE)₂. FIG. 4B shows the tuning hysteresis width H_{C} by chemistry, comparing the RT magnetization of V(TCNE)₂ relative to [V_{0.5}−Co_{0.5}]−(TCNE)₂. FIG. 4C shows the RT magnetization of V-TCNE-PVPy polymer.

It is relatively easy to tune the hysteresis width in the V(TCNE)₂ system by altering the chemistry, as shown in FIGS. 4A and 4B. H_{c} in a V(TCNE)₂ system can be tuned by current. The field in a V(TCNE)₂ system acts as a barrier to the spin-flipping mechanism. Controlling the current through a V(TCNE)₂ device should directly decrease this barrier (and thus H_{c}) and achieve nano-Tesla (nT) and sub-nT sensitivities.

A few fabrication problems can be addressed prior to the device application, including: (a) oxidation of V(TCNE)₂ that leads to degradation of the magnetic properties; and (b) insolubility of the V(TCNE)₂ in organic solvents. Currently V(TCNE)₂ is produced by a tedious method that relies on chemical vapor co-deposition in an inert environment. The first problem can be solved by hermetic encapsulation of the device during manufacture. The second problem has been addressed by combination of a polyvinyl pyridine polymer with V(TCNE)₂ [V-TCNE-(PVPy)], containing 30% of V-TCNE monomer coordinated to the polymer backbone. The resulting polymer has weaker magnetization (FIG. 4C) due to the non-conjugated structure of the polymer backbone, and a disturbing “spin-talking” system; but still has the same H_{C} as V(TCNE)₂. In addition the magnetic polymer was found to be more stable against oxidation.

A chemical doping of V(TCNE)₂ results in a V-Co(TCNE)₂ system, which remains an RT magnet, but has a tunable hysteresis width (FIGS. 4A and 4B). The hysteresis width is already below μT range and is promising for low field magnetic sensors. In addition a synthesis containing a first stable polymer, containing V(TCNE) moieties in a PVPy backbone (FIG. 4C). Note that polymer remains RT magnetic, with narrow hysteresis width. The width of the hysteresis loop in a V-TCNE system may be dependent on current flowing through molecular magnet. The V-TCNE-(PVPy) polymer is a soluble molecular magnet that is readily adapted to fabrication technologies. Magnetization in the polymer can be improved by using a polymer with a conjugated backbone system. No conductivity data exists for the V(TCNE)₂ system and the MR of this system can be explored in two terminal devices with nonmagnetic electrodes. In accordance with another embodiment of the present invention, configurations can include 1) AlN(TCNE)₂/ITO [bottom (LSMO)-up (Co) vertical design]; 2) Au/V(TCNE)₂/Au [horizontal FET-like design]; and 3) V(TCNE)₂/T6/V(TCNE)₂.

Device features related to magnetic sensor applications can include frequency resolution. According to optical diamagnetic resonance studies there is nano-femto-second scale for excitation and response relaxation in organic polymers. This relaxation time is favorable for high frequency applications of magnetic sensors. Furthermore, spatial resolution can be an important consideration. For a practical measurement of magnetic field it is important to have a 3D resolution in sensitivity of magnetic field spectra. Such 3D resolution can be achieved by placement of three magnetic field sensors in 3D orthogonal configuration. Each of these sensors can have nm scale electrodes to achieve required spatial sensitivity.

Long-range ferromagnetic order in SAM, molecular magnets and magnetic polymer (sensitive magnetometer element) can also be useful in connection with the present invention. Owing to the nature of the ligands, the alkyl chains do not participate directly in the interlayer coupling, but noticeable change can result in the magnitude of the in-plane interaction. It can be pointed out that: (1) antiferromagnetic in-plane correlations promote, for large basal spacing, an antiferromagnetic (AF) 2D short-range order; (2) for ferromagnetic in-plane interactions, the situation depends to a large extent on the interlayer spacing. For small spacing (less than 10 Å), the interlayer interactions via hydrogen bond superexchange pathways stabilize a 3D AF order, and a metamagnetic transition is observed in low field. When the spacing is made larger (large n values), the superexchange mechanisms can no longer be considered efficient. Nevertheless, the compounds exhibit a spontaneous magnetization and a characteristic hysteresis cycle. Such large ferromagnetic ordering temperatures and their weak dependence on the interlayer spacing can hardly be related to superexchange interactions. In turn, they can be explained by considering dipolar through-space interactions between layers.

The strength of the electrostatic exchange and dipolar interaction energies between two discrete moments at a distance r apart decreases crudely as r⁻¹⁰ and r⁻³ respectively. Clearly, the electrostatic interaction is by far the most important contribution for small r values but, in turn, becomes negligible compared with the dipole interaction for large distances. Consider a two-dimensional (xy) square lattice of spins S, coupled by ferromagnetic exchange interactions to their nearest neighbors. At absolute zero, the magnetic layer exhibits a ferromagnetic alignment of the spins due to exchange coupling, and the ground-state corresponds to the higher spin multiplicity. Upon increasing the temperature, the spins become correlated only on a finite distance ξ. For a 2D Heisenberg ferromagnet, this is related to the exchange constant J and the spin value S by the relationship:

ξ²=(JS/kT)exp(4πJS²/kT)

where ξ²gμBS is the effective paramagnetic moment, deduced from magnetization data. Here g, μ_{B}, and S are the electron g-factor (related to the electron gyromagnetic ratio), the Bohr magneton and the spin value, respectively. The basic idea is that the dipole interaction between layers stacked along the z-direction leads to 3D ordering as soon as the in-plane correlation length ξ reaches a threshold value related to the interlayer spacing c. Because of the exponential divergence of ξ, the temperature for which the threshold is reached should depend only weakly on c. In order to minimize the dipole and anisotropy energies, the order between layers is expected to be ferromagnetic if z is the easy axis.

Considering that the interlayer spacing c is large compared to the in-plane lattice parameter a, it is assumed that: the in-plane correlation length is determined only by the in-plane exchange interaction; any exchange interaction between layers is negligible, and only through-space dipole coupling is available between moments located in different layers; and a small local anisotropy favors the spin orientation normal to the layers.

Accordingly, each layer is considered as a chess board with alternating spin-up and spin-down squares, each one containing ξ² spins. Each square is thus considered as a superspin, the moment of which is ξ²gμBS=ξ²μ. The dipole field acting on a superspin due to all other superspins has been calculated and takes into account the spatial extension of the superspins. This expression can be rewritten as:

H_{dipole}=λ(ξ)<μ_{z}>

where λ is a coupling coefficient depending on the correlation length. In order to get a picture of the critical region, i.e. the transition to long-range order, a simple molecular field theory should be considered, where the molecular field is given by the dipole field. The magnetization of organics models predicts a long-range 3D ferromagnetic order, even for very large spacing between the magnetic layers. Such coupling is efficient, compared to the classical AF exchange mechanism, as long as the bridging ligands do not participate in electronic transfers. This result demonstrates that the design of molecular ferromagnets may involve complementary strategies. The choice of suitable bridging ligands to optimize the overlap between magnetic orbitals and accordingly the exchange interaction is clearly the pertinent way. The self-assembling of magnetic layers may also promote long-range magnetic correlations, and as a result 3D ordering. SAM hybrid layered compounds with tunable basal spacing thus appear promising for the design of new 3D ferromagnets.

In each embodiment of the present invention, the resistance of sensor devices, detected by electrical measurements, will vary based on an external magnetic field. The transport of charges and spin-transport in organic material are dependent on magnetic field, which we define above as magneto-transport.

The devices of the present invention can be prepared in a variety of ways. Magnetic (Co, Ni, Fe, LSMO) and non magnetic (ITO, Al etc) electrodes can be prepared just before deposition of organic layers. Following thin film deposition techniques can be used for electrode fabrication: as sputtering, thermal evaporation, Chemical vapor deposition (CVD) and organo-metallic CVD (OMCVD) derived methods.

As deposited electrodes can be exposed for plasma etching to (i) clean the surface and (ii) activate surface reactive cites for self-assembly process.

The environment for organic thin film deposition can be accomplished via a self-assembly process. The following non-limiting examples of self-assembling processes can proceed in air- and water isolating conditions using Shlenk line (modification: high vacuum Shlenk line), the Langmuir-Blodgett (LB) set up or Glove box for solution phase self-assembly using Ar or N₂ gas as air “protective” media. Insoluble precursor organic materials can be evaporated for self-assembly on the surface using CVD-like Molecular Layer Epitaxy (MLE) system.

The self-assembly process can proceed on different substrates, including ferromagnetic and half-metal ceramic electrodes and anchoring groups. Self-assembling process could be performed on noble metal surface as Ag, Au and Pt, and oxidized surfaces as clean hydroxylated metal-oxide surface, such as SiO₂, TiO₂, Al₂O₃; solid state mixed oxides as indium tin oxide (ITO), or pure ceramic electrode as LSMO. Coupling compounds can be used to make an intermediate template layer, between the substrate and an active organic molecular moiety can be used to make self-assembling on oxide electrodes. Oxide surfaces can be converted to an aminated surface by a solution phase reaction, e.g., with 4-aminopropyltrimethoxysilane in solution phase and vapor phase. Thiol reactive anchoring groups, (one-step chemical reaction) and other one and two step reactions can be used to build sulfide and other bonds with metals. Metals other than noble metal group, as Co, Ni, Fe, which are ferromagnets and thus important for magneto-transport applications, usually have a natural oxide on the surface, i.e. CoOₓ/Co. Nevertheless thiols can form a sulfide bond with such metal by two-step chemical reaction. The particularly highly oxidized Cu/CuO system was used as a self-assembly template. This was verified experimentally studying Co/CoO substrate. Here the surface chemistry of active amine on the hydroxylated metal-oxide surface, can be used for self-assembly on metallic ferromagnetic or ceramic ferromagnetic LSMO electrodes. In this case active hydroxyl surface groups reacts directly with amine functionality of active molecular wire or spacer, thus illuminating a need in intermediate dielectric silane layer, also known as a “template layer”.

Different molecules can be used for magnetic transport devices. A non-limiting example of molecular device and magneto-transport is a benzene molecule, with delocalized pi-electron system over the aliphatic connecting chains. This is an example of aromatic molecules which can include more than one ring, connected in line structure by aliphatic connectors. Larger molecular moieties as naphthalene, parylene, which have conjugation of aromatic rings or multi-aromatic ring systems as phthalocyanines, calixarenes, fullerenes, porphyrins, or DNA-derived structures can also be suitable. Metallo-organic molecules containing one or more metal atoms. Molecules which contains magnetic atoms, as Co, Fe, Ni, inside of aromatic shell, as, for example, Co-porphyrins and Co-phthalocyanine, complexes, are non-limiting examples of magnetic transport media; all other classes of metalloorganic compound belong to non-magnetic compounds.

Devices, which utilize a Kondo effect in metallo-organic molecules, have a magnetic atom inside. These materials and devices belong to magnetic type media of organic magnetic sensors. The Kondo effect is a many-body phenomenon resulting from the spin interaction between localized magnetic impurities and conduction electrons. Hybrid structures can also be based on organic molecules and magnetic quantum dots structures (OD), or broadly speaking any 1D or 2D structures with magnetic moieties.

Magnetic transport was demonstrated in single wall carbon nanotubes (SWCNTs) with ferromagnetic Co electrodes. Therefore magnetic transport in SWCNTs can also be used for magnetic sensor devices. SWCNTs walls and edges can be modified by self-assembling molecules, such hybrid structures can modify essentially magneto-transport in these hybrid devices and therefore can be used to tune sensitivity of magnetic sensors based on SWCNTs.

A new molecular electronic approach is also provided by the present invention, namely self-assembly in solid state solutions as shown in FIGS. 2A-D. Using this approach, conductive molecules can be diluted to get conductivity through isolated molecular wires, which are isolated in an insulating matrix of self-assembled spacer molecules. Using the aforementioned approach one can tune structural features in molecular diodes in the 1D-2D range. This opportunity is favorable for magnetic sensors, since magnetic transport is very sensitive to structural features.

Single-molecule magnets can be included in molecular self-assembly processes. Most of these molecular systems are polynuclear metal complexes formed by a magnetic cluster of exchange-coupled transition metal ions surrounded by shells of ligand molecules. In analogy to bulk magnets, these nano-scale magnetic materials exhibit slow relaxation of the magnetization with magnetic hysteresis. In addition new phenomena, quantum effects such as the quantum tunneling of the magnetization, can be utilized in developing new sensing devices.

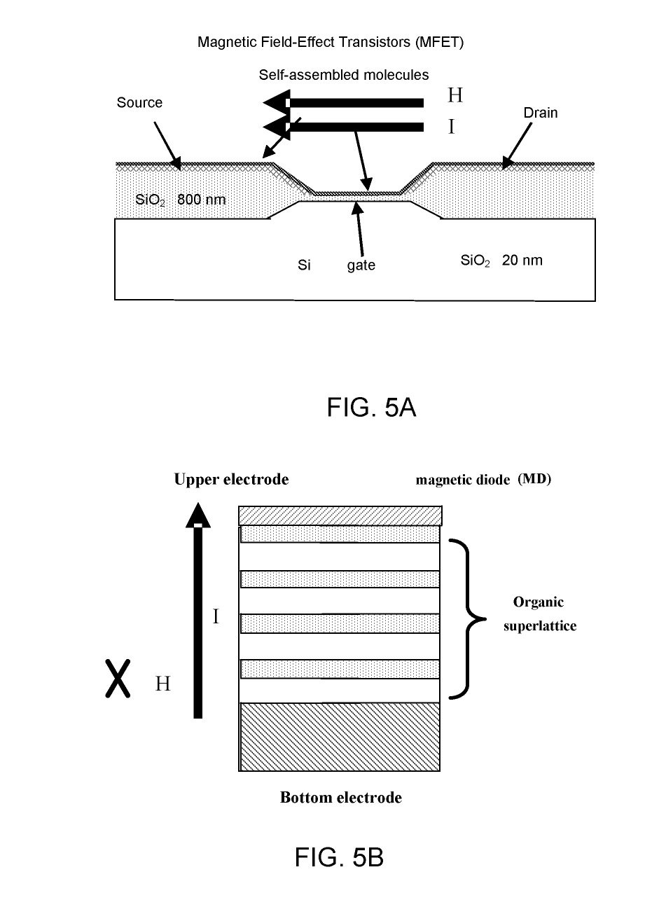

Devices of this type (semiconducting non-magnetic polymer, and magnetic electrodes) can be used in planar or in vertical configuration. A planar configuration can enable tuning through in-plane drain current by a gate field. FIGS. 5A-B summarizes additional device configurations of magnetic sensors based on magneto-transport. The magnetic sensor device configuration can be either horizontal (FIG. 5A) or vertical (FIG. 5B). Devices of A and B type can have magnetic, or non-magnetic electrodes as previously described. They can also be transparent and/or opaque to light. Active conductive media can be non-magnetic media, such as non-magnetic SAM; or organic semiconducting polymers, or use conductive monomers and polymers to that end. In the case of non-magnetic media magneto-transport, such is defined by conductivity phenomena of organic-electrode interface, which are known to depend from the magnetic field. Magnetic media can generally include magnetic polymers, such as V(TCNE)₂. Magnetic inclusions can comprise metallic, ceramic, and organic inclusions. Output signal in these devices might be reordered in form of electrical signal (bias or current) or light. In the last case the device can act as an organic light emission diode, which electroluminescence will be depended from applied magnetic field. Organic-electrode interfaces may include injected interface barriers, which can be used for additional tuning of tunneling rate through the interface-injecting barrier. Since the fields where magnetoresistance of these devices have a maximum position which depends on the difference of the coercive field in different electrodes (FIG. 3C), the magnetic sensitivity can be easily tuned in a low strength magnetic field by selecting proper electrode materials.

Field sensors using magnetic and electromagnetic fields molecular magnets (molecular polymers) can be formed in a number of ways. There are two methods to deposit magnetic polymer on the electrode surfaces: the first is a vapor phase deposition process of initial precursor materials. Alternatively, a polymer can be synthesized, which can exhibit magnetism at room temperature, and then such a polymer can be dissolved in an organic solvent and produce a thin film using spinner set up technologies on any surface including magnetic or non-magnetic electrodes. Vapor phase deposition of molecular magnets (magnetic polymer) can proceed using the protocol developed for a deposition of V(NCNE)₂ compounds, which are high temperature magnets. These molecular magnets can have the structure which contains small molecules, which are physically overlapped with each other producing a continuous thin film media.

Sensors based on V(TCNE)₂ for the sensing element have a high potential for magnetic sensing since this compound is a room temperature ferromagnet with extremely low H_{c} (6 μT) (FIGS. 5A and 5B). In addition it is relatively easy to tune the hysteresis width in the V(TCNE)₂ system by altering the chemistry. Other molecular and organometallic magnets can be deposited using similar technology. These materials include purely organic ferromagnets, which contain only s and π electrons, free radicals (such as benzoic acid-substituted imino-nitroxide (IMBA) radical, thiazyl radicals, dithiadiazolyl radicals, spirp-biphenalenyl borate, triarylaminimum polyradical, di-2-pyridyl ketoximate ligand, etc), either electron spin residing on non-metallic sites.

Soluble Magnetic Polymers

A few fabrication problems addressed include: (a) oxidation of V(TCNE)₂ that leads to degradation of the magnetic properties; and (b) insolubility of the V(TCNE)₂ in organic solvents. Currently, V(TCNE)₂ is produced by a tedious method that relies on chemical vapor co-deposition in an inert environment. The first problem can be solved by hermetic encapsulation of the device during manufacture. The second problem has been addressed by a combination of a polyvinyl pyridine polymer with V(TCNE)₂ [V-TCNE-(PVPy)], containing 30% of V-TCNE monomer coordinated to the polymer backbone. The resulting polymer has weaker magnetization (FIG. 4C) due to the non-conjugated structure of the polymer backbone, and a “spin-talking” system; but still has the same H_{C} as V(TCNE)₂. In addition the magnetic polymer was found to be more stable against oxidation.

Structure of V-TCNE Compounds

Magnetic polymers can be considered as layered nanostructures with alternating conducting and magnetic networks. These polymers have been the subject of thorough studies to understand the interplay of magnetism and conductivity and the novel properties resulting from this combination such as the observation of field-induced magnetic transitions. In particular, the H_{c} in a V(TCNE)₂ system can be tuned by current. The H_{c} field in a V(TCNE)₂ system acts as a barrier to the spin-flipping mechanism. Controlling the current through a V(TCNE)₂ device can directly decrease this barrier (and thus H_{c}) and achieve nano-Tesla (nT) and sub nT sensitivities.

One can tune the system on two levels. First a polymer V(TCNE)-derived system can be adjusted chemically, i.e. chemistry can tune an initial hysteresis loop. For example, in a V-TCNE system the addition of Co atoms initially increases and after certain concentration is reached, decreases the resulting hysteresis loop, when compared with a pure V(TCNE)₂ system.

While using current in a device, which has a “pre-tuned” V(TCNE)₂ system and non-magnetic electrodes, very fine tuning of the H_{c} width of the hysteresis loop is enabled. This provides maximal sensitivity of magnetic transport (I) (see FIG. 1) as a function of applied field and passed current. At the same time the output value of magneto-transport measurement (relative ΔR/R value) will not be affected by the value of absolute current passed though the device.

Self-assembling of small molecules with properties of molecular magnets is another optional embodiment, which combines advantages of molecular self-assembly with magnetism in small molecule containing systems.

Magneto-transport devices based on molecular magnets and magnetic polymers. A variety of devices suggested previously can be used for incorporation of molecular magnetic media into magneto-transport devices and suggested type of magnetic sensors. Magnetic field sensors can also be formed. A variety of polymer semiconductive media and devices summarized previously, such as those illustrated in FIG. 5, can be used.

Magnetism in Self-Assembled Stacks of Organic-Inorganic Subnetworks.

Self-assembled stacks of organic-inorganic subnetworks can promote very long-range magnetic correlations. A 3D ferromagnetic order illustrates the key role of dipolar interactions. These are also relevant metal-radical compounds, even if the organic (radical) and inorganic spins are likely coupled through the π-system of the benzoic acid. The present result points to the fact that the divergence of the correlation length, and as a result the mean spin value within the ferromagnetic layers, is an important feature to promote the dipolar effects responsible for the 3D ordering. In this respect, this family of layered hybrid systems differs basically from the classical radical-based molecular compounds (namely, radicals complexed to metal ions), and is one suitable design of new kinds of ultra-sensitive sensors based on ferromagnets.

Magnetic Sensors Based on “Switching Magnetic Materials”

An extensive class of magnetic materials of this type are the so-called “switching magnetic materials”. These molecular materials exhibit bistability at the molecular level and therefore their magnetic properties can be tuned by the application of external stimuli (light, pressure, temperature, electrical field etc). Archetypes of switching magnetic materials are the so-called spin-crossover compounds and the magnets based on Prussian Blue analogues for which temperature-switching, light-switching, and pressure-switching have been demonstrated. Furthermore, on a truly molecular basis, cyanide bridged high-spin clusters have recently been identified as photo-physically active. Photo-induced electron transfer has been shown to influence the magnetic properties of the metal complex. Finally, other classes of interesting optomagnetic materials are the so-called chiral magnets in which the coupling between chirality and ferromagnetism may result in the observation of novel physical properties (magneto-chiral dichroism). Due to their switchable properties, the above materials are useful for sensing in two ways. First their sensitivity can be tuned by external stimuli, see above, and, second, these materials can have an analog output of sensed signal (i.e. the material can emit light, if a magnetic field threshold is achieved)

The above description is intended only to illustrate certain potential embodiments of this invention. It will be readily understood by those skilled in the art that the present invention is susceptible of a broad utility and applications. Many embodiments and adaptations of the present invention other than those herein described, as well as many variations, modifications and equivalent arrangements will be apparent from or reasonably suggested by the present invention and the foregoing description thereof without departing from the substance or scope of the present invention. Accordingly, while the present invention has been described herein in detail in relation to its preferred embodiment, it is to be understood that this disclosure is only illustrative and exemplary of the present invention and is made merely for purpose of providing a full and enabling disclosure of the invention. The foregoing disclosure is not intended or to be construed to limit the present invention or otherwise to exclude any such other embodiment, adaptations, variations, modifications and equivalent arrangements, the present invention being limited only by the claims appended hereto and the equivalents thereof.

1. A system for measuring a magnetic field, comprising:
at least two electrodes;
a sensing channel comprising an organic material located between the at least two electrodes; and
a magnetic field detection device coupled to the at least two electrodes and configured to determine a strength of the magnetic field based on a change in current flow through the sensing channel.

2. The system of claim 1, wherein the magnetic field detection device measures at least one of a current and a voltage between the at least two electrodes.

3. The system of claim 1, wherein:
the at least two electrodes are magnetic electrodes, and
the sensing channel comprises a non-magnetic organic material.

4. The system of claim 3, further comprising an ammeter operable to measure a spin current flow through the sensing channel caused by the magnetic field.

5. The system of claim 3, wherein the non-magnetic organic material is selected from the group consisting of at least one polymer and at least one self-assembled monolayer.

6. The system of claim 5, wherein the self-assembled monolayer comprises a solid state mixture of conductive molecular wires and dielectric spacers.

7. The system of claim 6, wherein the conductive molecular wires are composed of Me-BDT, the dielectric spacers are composed of pentanethiol, and the at least two electrodes comprise cobalt.

8. The system of claim 1, wherein the organic material comprises a multilayered composite structure including a self-assembled monolayer and a second layer.

9. (canceled)

10. The system as in claim 1, wherein the organic layer comprises a self-assembled stack of organic-inorganic subnetworks.

11. The system of claim 1, wherein the organic material comprises at least one of fullerenes, graphene, carbon nanotubes, and single wall carbon nanotubes.

12. The system of claim 1, wherein the at least two electrodes are composed of at least one material selected from the group consisting of LaMn₂Sr₃O₃ (LSMO), La₍₁₋ₓ₎SrxMnO₃ where x=0.7, La_{0.7}Sr_{0.3}MnO₃, La_{1.2}Sr_{1.8-x}CaₓMn₂O₇ (where x=0, 0.1, 0.2), La_{0.75}Sr_{0.25-x}MgₓMnO₃, Pr_{0.7}Sr_{0.3}MnO₃, Ln_{0.67}A_{0.33}MnO₃ (where Ln=Pr or La, and A=Ca or Sr), Co, Ni, Fe, Gd, CrO₂, FeOFe₂O₃, NiOFe₂O₃, MgOFe₂O₃, MnBi, MnSb, MnAs, EuO, Y₃Fe₅O₁₂ permalloy (FeNi), Fe—Cr—Co, alloys thereof, and combinations thereof.

13. The system of claim 1, wherein the sensing channel comprises a magnetic organic material located between the at least two electrodes.

14. The system of claim 13, wherein the magnetic organic material comprises a polynuclear metal complex formed by a magnet cluster of exchange coupled transition metal ions surrounded by at least one shell of ligand molecules.

15. The system of claim 13, wherein the sensing channel is formed from bis-tetracyanoethylene vanadium (V(TCNE)₂).

16. The system of claim 13, wherein the sensing channel is formed of a cobalt doped V(TCNE)₂—polyvinyl pyridine polymer.

17. The system of claim 1, further comprising a light emitting material embedded in at least one of the organic material and the at least two electrodes in an amount sufficient to act as a visual magnetic field intensity indicator.

18. The system of claim 17, wherein the light emitting material is selected from the group consisting of an electroluminescent phosphor, a nanodot containing polymer, and a light emitting polymer.

19. The system of claim 1, further comprising at least three sensing channels, wherein each sensing channel is substantially orthogonal to the other of the at least three sensing channels to provide magnetic detection in three dimensions.

20. A method of measuring a magnetic field, comprising measuring a flow of non-tunneling electrons through an organic media caused by the magnetic field, wherein the organic media is located between at least two electrodes and the flow of electrons in the organic media is related to a strength of the magnetic field.

21-25. (canceled)

26. A method of manufacturing a magnetic field sensor, comprising:
forming a pair of electrodes spaced apart from one another;
forming an organic layer positioned between the pair of electrodes to form an organic solid state device, wherein at least one of the organic layer and the pair of electrodes is magnetic and when the organic layer is not magnetic the organic layer comprises a self assembled monolayer and the magnetic field sensor operates under non-tunneling magnetic spin transport.

27-30. (canceled)
